(19) United States
(12) Patent Application Publication
(10) Pub. No.: US 2009/0277388 A1
(43) Pub. Date: Nov. 12, 2009

(54) HEATER WITH DETACHABLE SHAFT

(75) Inventor: DMITRY LUBOMIRSKY, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/255,829

(22) Filed: Oct. 22, 2008

Related U.S. Application Data
(60) Provisional application No. 61/052,078, filed on May 9, 2008.

(51) Int. Cl. C23C 16/54

(52) U.S. Cl. 118/725

(57) ABSTRACT

Embodiments of the present invention generally include an apparatus for uniform heat distribution across the surface of a substrate during processing. The apparatus includes a substrate heater with a heated substrate support surface that is removable attached to a heater shaft via a fastening mechanism. The interface between the heated substrate support and the heater shaft may include a soft metal gasket and a vacuum or purge channel disposed therein. The substrate support surface may include regions for independently varying the back pressure of a substrate disposed thereon.

### CROSS-REFERENCE TO RELATED APPLICATIONS

This application claims benefit of U.S. provisional patent application Ser. No. 61/052,078, filed May 9, 2008, which is herein incorporated by reference.

### BACKGROUND OF THE INVENTION

1. Field of the Invention

Embodiments of the present invention generally relate to an apparatus for providing uniform thin film deposition across a substrate. More particularly, embodiments of the present invention relate to a substrate support heater that provides uniform temperature distribution across a substrate, while minimizing the cost of ownership.

2. Description of the Related Art

A primary step in the fabrication of modern integrated circuits involves the formation of an insulating film, such as a silicon dioxide film, on a substrate. One such insulating film is a pre-metal dielectric (PMD) film. The PMD film insulates the substrate from a first metal layer, and provides the base film upon which numerous other layers are deposited. Thus, in order to control the uniformity of features formed in the fabrication of integrated circuits, the uniformity of the PMD film deposited across the substrate is critical.

One problem associated with sub-atmospheric chemical vapor deposition (SACVD) processes used in manufacturing of integrated circuits is non-uniformity of the thickness of films, such as PMD films, deposited across the substrate. Such non-uniformity may be due, in part, to non-uniform temperature distribution across the substrate.

In SACVD processes, reactive gases are introduced into a reaction chamber at sub-atmospheric pressures. The reactive gases flow over the heated substrate (e.g. 500-600° C.), where desired chemical reactions occur, and the film is deposited. Unwanted deposition occurs on areas such as a substrate support surface of a substrate heater situated within the reaction chamber. It is common to remove the unwanted deposited material from the surface of the heater with in situ chamber clean operations. Common chamber cleaning techniques include the use of an etchant gas, such as nitrogen trifluoride (NF₃), to remove the deposited material from the substrate support surface.

However, typical substrate heaters are made from aluminum, aluminum oxide, or aluminum nitride. One problem with using NF₃ or other fluorine-containing etchant gases for cleaning unwanted deposits from these aluminum-containing heaters after a high temperature deposition process is that active fluorine species from the etchant gas reacts with the aluminum, resulting in the formation of AlF₃ film on the surface of the substrate heater. This film has relatively high vapor pressures and relatively low sublimation temperatures and may attain a thickness of several hundred micrometers when conditions for self-passivation are not met, such as at the outer annular region of the substrate supporting surface of the substrate heater.

The build-up of AlF₃ film on the uncovered and/or partially covered edge region of the substrate supporting surface of the substrate heater results in uneven thermal conduction between the heater and the substrate, resulting in uneven temperature distribution across the substrate. In order to deal with this problem, the industry practice is to polish the substrate supporting surface, at specified intervals, to remove the AlF₃ film. However, the substrate supporting surface of the substrate heater is consumed after only a few of the polishing processes, and the entire substrate heater must be replaced at significant cost.

Therefore, a need exists for a heater pedestal that promotes uniform film deposition by increasing the temperature uniformity across the substrate, while minimizing the cost of ownership.

### SUMMARY OF THE INVENTION

In one embodiment of the present invention, a substrate heater comprises a substrate support member comprising a ceramic material and having a heating element disposed therein, a shaft member having an upper flange configured to support the substrate support member, and a fastening member configured to removably attach the substrate support member to the upper flange of the shaft member.

In another embodiment of the present invention, a processing chamber comprises a chamber wall, a gas distribution showerhead, a vacuum source, a valve member in fluid communication with the vacuum source at an input location, a controller, and a substrate heater. In one embodiment the substrate heater comprises a substrate support member have an upper surface for supporting a substrate thereon and a heating element disposed therein, a hollow shaft member having an upper surface configured to mate to a lower surface of the substrate support member, and a fastening member configured to removably attach the lower surface of the substrate support member to the upper surface of the hollow shaft member. In one embodiment, the substrate support member is comprised of a ceramic material. In one embodiment, the hollow shaft member has an annular groove in the upper surface thereof.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic, cross-sectional view of an exemplary SACVD system that may incorporate embodiments of the present invention.

FIG. 1B is an enlarged, schematic, cross-sectional view of the gas delivery system in FIG. 1A.

FIG. 2 is a schematic, cross-sectional view of a substrate heater assembly according to one embodiment of the present invention.

FIG. 3 is a top view of the heater plate in FIG. 2.

FIG. 4 is a top layout view of a heater element according to one embodiment of the present invention.

### DETAILED DESCRIPTION

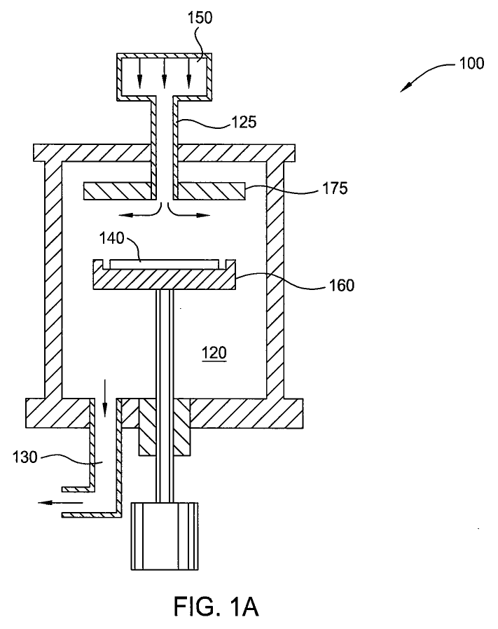

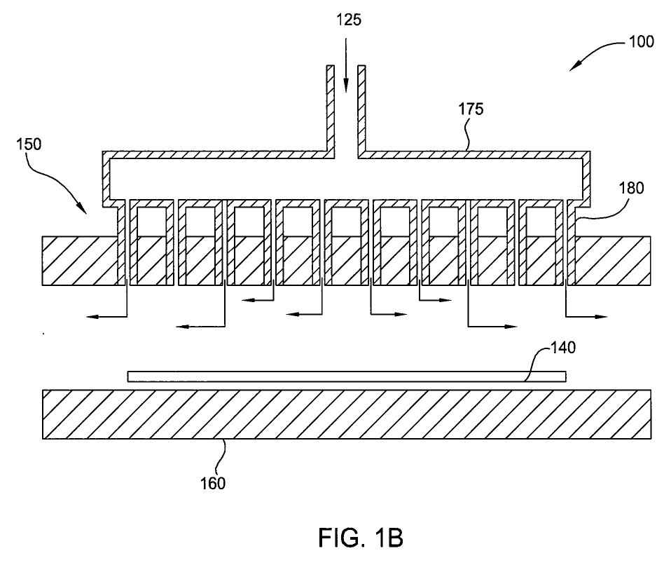

FIG. 1A is a schematic, cross-sectional view of an exemplary SACVD system 100 that may incorporate embodiments of the present invention. The system 100 includes a chamber 120, a gas delivery system 150, a substrate heater assembly 160, and a vacuum system 130. Reactive gases are introduced into the reaction chamber 120 through an inlet 125 of the gas delivery system 150. The substrate heater assembly 160 supports and heats a substrate 140. In order to promote a uniform distribution, the reactive gases are introduced into the chamber 120 from a source positioned opposite the substrate 140. The gas delivery system 150 may include a heating and cooling means (not shown) for maintaining a constant gas and chamber temperature. The substrate 140 is transferred into and out of the chamber 120 by a transfer robot (not shown) through an opening (not shown) in the side of the chamber 120.

FIG. 1B is an enlarged, schematic, cross-sectional view of the SACVD system 100 illustrating the gas delivery system 150. Reactive gasses are introduced through the inlet 125 into a heated showerhead 175. The shower head 175 has a plurality of outlets 180 disposed at specified intervals. The reactive gasses flow over the heated substrate 140 and deposit a thin film thereon.

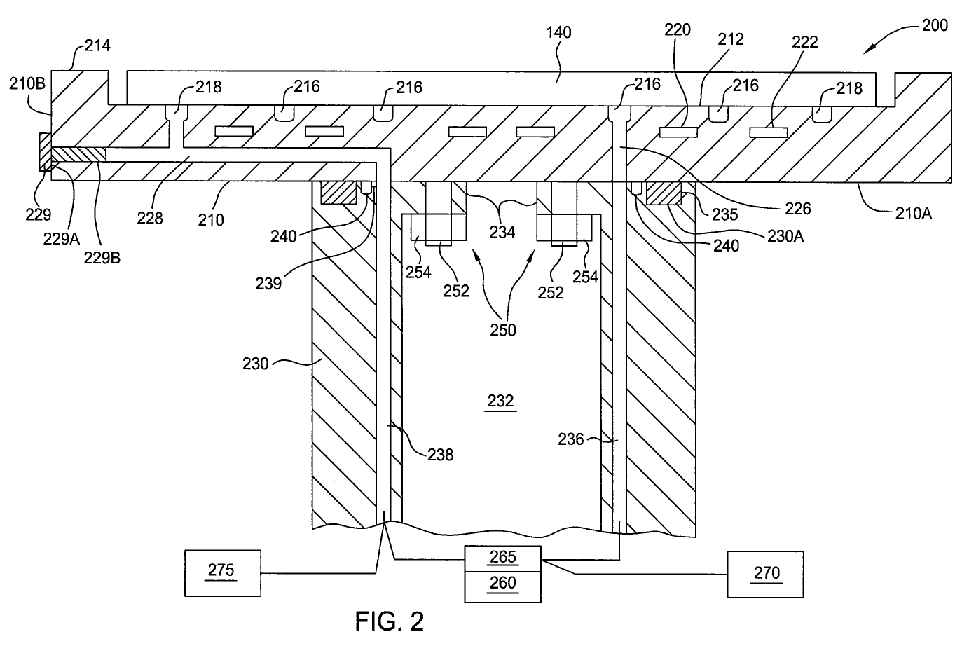

FIG. 2 is a schematic, cross-sectional view of a substrate heater assembly 200 according to one embodiment of the present invention. The heater assembly 200 includes a heater plate 210 for supporting and heating the substrate 140. In one embodiment, the heater plate 210 is substantially disk shaped having an appropriately sized upper surface for supporting the substrate 140. The heater plate 210 may comprise a ceramic material with good thermal conducting characteristics. In one embodiment, the heater plate 210 may comprise aluminum nitride. The heater plate 210 may be formed by sintering multiple layered sheets of a “green” phase ceramic material, such as aluminum nitride as known in the art.

The heater plate 210 is detachably coupled to a heater shaft 230. The heater shaft 230 is substantially cylindrical having a hollow interior volume 232. The heater shaft 230 includes an upper flange 234 for mounting to the heater plate 210. In one embodiment, the upper flange 234 extends into the interior volume 232. The heater shaft 230 may comprise a ceramic material having a thermal conductance less than that of the heater plate 210. In one embodiment, the heater shaft 230 may comprise aluminum oxide and the heater plate 210 may comprise aluminum nitride.

In one embodiment, the heater plate 210 is detachably coupled to the heater shaft 230 via two or more fasteners 250. Each fastener 250 may comprise a threaded stud 252 permanently attached to the heater plate 210. In one embodiment, each threaded stud 252 is a metal (e.g., Kovar, SST) that is brazed to the bottom surface of the heater plate 210. When the heater plate 210 is mated to the heater shaft 230, each stud 252 extends through a corresponding aperture in the upper flange 234 of the heater shaft 230. A nut 254 is then threaded onto each stud 252, and the appropriate torque is applied to achieve a seal between the heater plate 210 and the heater shaft 230. Alternatively, the each fastener 250 may comprise a screw (not shown) inserted through the upper flange 234 and threaded into threaded holes (not shown) in the bottom surface of the heater plate 210.

In one embodiment, the sealing surfaces of the heater plate 210 and the heater shaft 230 are polished to promote a good seal. In one embodiment, the roughness of each of the sealing surfaces is between about 0.40 microns (μm) and about 0.01 microns. In one embodiment, an annular gasket 236 is disposed between the mating surfaces of the heater plate 210 and the heater shaft 230 to promote a better seal. The gasket 236 may be a soft metal, such as aluminum. It is believed that the aluminum gasket 236 may plastically deform at operating temperatures (such as 500° C.-600° C.), resulting in good conformance to the mating surfaces of the heater plate 210 and the heater shaft 230. In one embodiment, the annular gasket is disposed within a groove 230A formed in the heater shaft 230 to support and retain the annular gasket 236. In one embodiment, the groove 230A and the back surface 210A of the heater plate 210 each have at least one raised area (not shown) that is in contact with a portion of the annular gasket 236 to improve the seal formed between the annular gasket 236, the heater plate 210, and the heater shaft 230. The raised areas are used to increase the contact stress between the annular gasket 236, the heater plate 210, and the heater shaft 230 when the heater shaft 230 is attached to the heater plate 210 to improve the formed seal.

Several advantages may be achieved over the prior art by the preceding configuration. In one embodiment, the height of the heater shaft 230 may be significantly shorter than that of prior art unitary substrate heaters. Typical prior art substrate heaters comprise unitary or permanently bonded structures. As such the material properties, such as thermal conductance, of the heater plate portion and the heater shaft portion are substantially identical. Therefore, the height of the shaft must be significant to adequately choke the heat transferred from the heater plate through the shaft. Conversely, embodiments of the present invention provide the heater shaft 230 made of a material having lower thermal conductance than that of the heater plate 210. Thus, the height of the heater shaft 230 may be significantly shorter than that of the prior art to achieve the same or better heat choking effect. Therefore, embodiments of the present invention provide a heater shaft 230 comprising less material than that of the prior art, and consequently, less costly than that of the prior art.

Additionally, embodiments of the present invention provide a lower cost of ownership than that of the prior art. For instance, as previously described, the surface of heater plates must be polished periodically to remove AlF₃ film deposits. In prior art substrate heaters, after a few polishing procedures, the entire heater assembly (including the heater shaft) must be removed and discarded. Therefore, the entire heater assembly is a consumable part in prior art configurations. In contrast, in embodiments of the present invention, only the heater plate 210 need be removed and replaced. Thus, in the present invention, the heater plate 210 is a consumable part, and the heater shaft 230 is a reusable part.

In one embodiment, the heater shaft 230 is a hollow shaft. Heater terminals (not shown), an RF terminal (not shown), and a thermocouple (not shown) may be located within the inner volume 232 of the heater shaft 230. In one embodiment, the heater shaft 230 includes shaft channels 236, 238 disposed therethrough. In one embodiment, the shaft channel 236 is coupled to a vacuum source 260 for vacuum chucking a substrate to the heater plate, as subsequently described. In one embodiment, the shaft channel 238 is coupled to the vacuum source 260 as well. In one embodiment, a valve 265 is positioned between the vacuum source 260 and the shaft channels 236, 238. The valve may be controlled by controller 270, which may be programmed to vary the gas conductance through the shaft channels 236, 238 to the vacuum source 260 to achieve a different vacuum pressure in each of the shaft channels and components connected to the respective shaft channels. In another embodiment, the shaft channel 238 is coupled to a purge gas source 275 that is adapted to deliver a gas to the shaft channel 238.

In one embodiment, the upper surface of the heater shaft 230 includes an annular groove 240 disposed therein. The annular groove 240 may be coupled to the shaft channel 238 via shaft channel 239. In one embodiment, vacuum pressure is applied to the groove 240 to remove atmospheric gas that may leak from the inner volume 232 of the heater shaft or to remove reactive gasses that may leak past the seal prior to reaching the inner volume 232. In another embodiment, a purge gas is supplied through the groove 240 to prevent leakage of gases past the sealing surfaces of the heater plate 210 and the heater shaft 230.

In one embodiment (not shown), the annular groove 240 is disposed within the back surface 210A of the heater plate 210 and coupled to the shaft channel 238. In one embodiment (not shown), both the back surface 210A and the upper surface of the heater shaft 230 have a groove 240 disposed therein and coupled to the shaft channel 238.

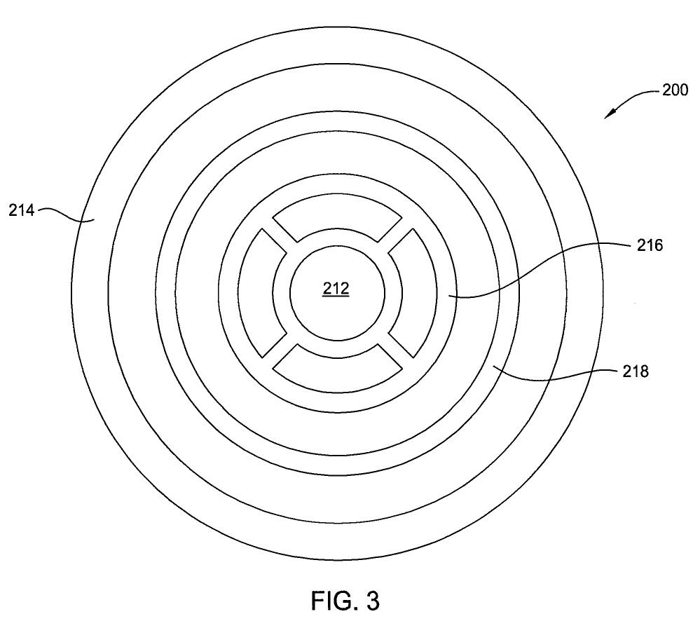

FIG. 3 is a top view of the heater plate 210 from the heater assembly 200 in FIG. 2. In one embodiment, the heater plate 210 may have a substrate support surface 212 surrounded by a raised annular flange 214. In one embodiment, the heater plate 210 has an inner groove 216 disposed in the substrate support surface 212. In one embodiment, the heater plate 210 has an outer groove 218 disposed in the substrate support surface 212.

In one embodiment, the inner groove 216 is coupled to the shaft channel 236 via a heater plate channel 226. The shaft channel 236 supplies vacuum pressure to the inner groove 216 for vacuum chucking a substrate to the substrate support surface 212. In one embodiment, the outer groove 218 is coupled to the shaft channel 238 via a heater plate channel 228. The shaft channel 238 may supply vacuum pressure to the outer groove 218 for chucking the substrate to the substrate support surface 212 as well.

In one embodiment, the vacuum pressure may be varied such that the vacuum applied to the substrate through the outer groove 218 is less or greater than the vacuum applied to the substrate through the inner groove 216. This configuration allows the contact pressure between the back surface of the substrate 140 and the heater plate 210 to be varied and controlled across different regions of the substrate 140, thus resulting in greater control of the heat transfer and temperature uniformity across the substrate during processing. As such, the heat distribution across the substrate may be substantially uniform, resulting in a more uniform film deposition across the substrate.

In another embodiment, purge gas may be provided to an outer peripheral region of the substrate through the outer groove 218. The flow of purge gas may reduce deposition in unwanted areas of the substrate and the heater plate 210. Additionally, the flow of purge gas may increase the heat transfer between the heater plate 210 and the outer peripheral region of the substrate, resulting in a more uniform heat distribution across the substrate. Thus, a more uniform film deposition across the substrate may be achieved.

Referring to FIG. 2, fabrication of the heater plate channel 228 may be accomplished via various techniques. In one embodiment, the heater plate 210 may comprise sheets of “green” phase material sintered to form a unitary body. In one embodiment, slots may be formed in one or more layer(s) within the stacked layers of “green” phase material prior to sintering to form the heater plate channel 228. In another embodiment, the channel 228 may be drilled from the side 210B of the heater plate 210. A plug 229 is inserted into the drilled hole and bonded to the side of the heater plate 210. Bonding may be performed by use of a high temperature adhesive material or by bonding of the plug 229 to the heater plate 210 by use of a sintering process. In one embodiment, it is desirable to assure that the seal formed between the plug 229 and the heater plate 210 is formed between a surface 229A of the plug 229 and the side 210B of the heater plate 210 to reduce the need for maintaining tight tolerances between the channel 228 and plug shank 229B.

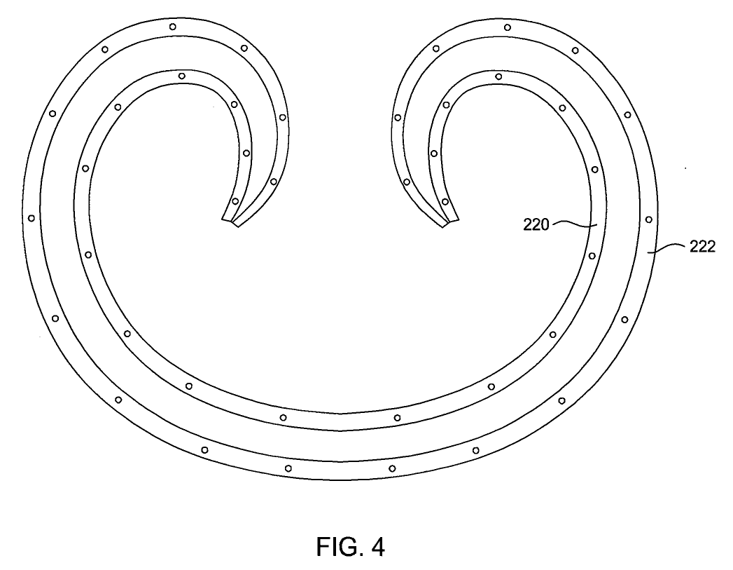

One or more heating elements 220 are embedded within the heater plate 210. FIG. 4 is a schematic view of a heating element 220 layout according to one embodiment of the present invention. In one embodiment, the heating element 220 comprises a wire of a material having good stability at high operating temperatures, such as tungsten or molybdenum. In one embodiment, the heating element 220 may be a screen printed layer. In one embodiment, the heating element 220 may be a tungsten or molybdenum wire mesh. In one embodiment, the heating element 220 is comprised of a substantially planar strip of perforated foil. The substantially planar shape provides positional stability in the fabrication process as opposed to a cylindrical wire. In addition, the perforated surface allows displacement of the heater plate 210 material during fabrication through the perforations in the heating element 220, again resulting in greater positional stability than prior art wires. The positional stability can improve the temperature uniformity across the substrate supporting surface 212 by reducing the variation in distance between the heating element 220 and the substrate supporting surface 212. In one embodiment, the perforated foil may comprise tungsten or molybdenum.

In one embodiment, shown in FIG. 4, the heating element 220 comprises two or more heating elements 220, 222 electrically connected in parallel and routed throughout the heating plate 210. The parallel heating elements 220, 222 allow greater distribution and control of the heat density across the surface of the substrate, resulting in more uniform heat distribution across the substrate. Therefore, a more uniform film distribution across the substrate may be achieved.

While the foregoing is directed to embodiments of the present invention, other and further embodiments of the invention may be devised without departing from the basic scope thereof, and the scope thereof is determined by the claims that follow.

1. A substrate heater, comprising:
a substrate support member comprising a ceramic material and having a heating element disposed therein;
a shaft member having an upper flange configured to support the substrate support member; and
a fastening member configured to removably attach the substrate support member to the upper flange of the shaft member.

2. The substrate heater of claim 1, wherein the shaft member has a central aperture extending therethrough and wherein the fastening member is located within the central aperture.

3. The substrate heater of claim 1, wherein the fastening member comprises at least two threaded studs bonded to the substrate support member.

4. The substrate heater of claim 1, further comprising an annular gasket disposed between the shaft member and the substrate support member.

5. The substrate heater of claim 4, wherein the annular gasket comprises aluminum.

6. The substrate heater of claim 1, wherein the shaft member comprises a ceramic material that is different from the ceramic material the substrate support member comprises.

7. The substrate heater of claim 1, wherein the substrate support member comprises aluminum nitride and the shaft member comprises aluminum oxide.

8. The substrate heater of claim 1, wherein an annular groove is disposed in one or both of an upper surface of the shaft member and a lower surface of the substrate support member, and wherein the annular groove is in fluid communication with a vacuum source.

9. The substrate heater of claim 1, wherein an annular groove is disposed in one or both of an upper surface of the shaft member and a lower surface of the substrate support member, and wherein the annular groove is in fluid communication with a purge gas source.

10. The substrate heater of claim 1, wherein the substrate support member has a first groove and a second groove disposed in a substrate support surface thereof and wherein the first groove is in fluid communication with a first channel formed in the shaft member and the second groove is in fluid communication with a second channel formed in the shaft member.

11. The substrate heater of claim 10, further comprising:
a vacuum source in fluid communication with the first and second channels;
a valve member in fluid communication with the vacuum source and configured between the vacuum source and the first and second channels; and
a controller programmed to independently vary the vacuum pressure supplied to the first and second channels.

12. The substrate heater of claim 10, further comprising:
a vacuum source in fluid communication with the first channel; and
a purge gas source in fluid communication with the second channel.

13. The substrate heater in claim 10, wherein the first groove is disposed in a central region of the substrate support surface of the substrate support member and the second groove is disposed in a peripheral region of the substrate support surface of the substrate support member.

14. The substrate heater of claim 1, wherein the heating element comprises at least two elements connected in parallel.

15. The substrate heater of claim 1, wherein the heating element comprises a substantially planar strip of perforated metal foil.

16. A processing chamber, comprising:
a chamber wall;
a gas distribution showerhead;
a vacuum source;
a valve member in fluid communication with the vacuum source at an input location;
a controller and
a substrate heater, comprising:
a substrate support member have an upper surface for supporting a substrate thereon and a heating element disposed therein, wherein the substrate support member is comprised of a ceramic material;
a hollow shaft member having an upper surface configured to mate to a lower surface of the substrate support member, wherein the hollow shaft member has an annular groove in the upper surface thereof; and
a fastening member configured to removably attach the lower surface of the substrate support member to the upper surface of the hollow shaft member.

17. The processing chamber of claim 16, wherein the substrate support member has a first groove and a second groove disposed in the upper surface thereof, wherein the first groove is in fluid communication with a first channel disposed in the shaft member and the second groove is in fluid communication with a second channel disposed in the shaft member.

18. The processing chamber of claim 17, further comprising a valve member in fluid communication with the first channel at a first output and with the second channel at a second output, and wherein the controller is programmed to send signals to the valve member for independently varying the vacuum pressure in the first and second channels.

19. The processing chamber of claim 18, wherein the first groove is disposed in a central region of the upper surface of the substrate support member and the second groove is disposed in a peripheral region of the upper surface of the substrate support member.

20. The processing chamber of claim 16, wherein the annular groove is in fluid communication with the vacuum source.

21. A substrate heater assembly, comprising:
a substrate support member having a substrate support surface and a heating element disposed therein;
a first groove disposed in the substrate support surface and in fluid communication with a first port formed in the substrate support member;
a second groove disposed in the substrate support surface and in fluid communication with a second port formed in the substrate support member;
a vacuum source in fluid communication with the first port and the second port;
a valve member in fluid communication with the vacuum source and the first port or the second port; and
a controller in communication with the valve member, wherein the controller is adapted to independently vary the pressure in the first channel or the second channel by controlling the gas conductance through the valve member.
